(19) United States
(12) Patent Application Publication
(10) Pub. No.: US 2013/0069170 A1
(43) Pub. Date: Mar. 21, 2013

(54) ILLUMINATION AND DESIGN RULE METHOD FOR DOUBLE PATTERNED SLOTTED CONTACTS

(71) Applicant: TEXAS INSTRUMENTS INCORPORATED, Dallas, TX (US)

(72) Inventor: James Walter Blatchford, Richardson, TX (US)

(73) Assignee: TEXAS INSTRUMENTS INCORPORATED, Dallas, TX (US)

(21) Appl. No.: 13/622,959

(22) Filed: Sep. 19, 2012

Related U.S. Application Data
(60) Provisional application No. 61/536,340, filed on Sep. 19, 2011.

(51) Int. Cl. H01L 23/50; H01L 21/768

(52) U.S. Cl. 257/401; 438/613; 257/E23.079; 257/E21.577

(57) ABSTRACT

An integrated circuit with long rectangular contacts to active where the active contact length is 2 times or more larger than the width and with short rectangular contacts to transistor gates where the transistor gate contact length is less than about 3 times the width. A method for forming an integrated circuit with long rectangular contacts to active where the active contact length is 2 times or more larger than the width and with short rectangular contacts to transistor gates where the transistor gate contact length is less than about 3 times the width.

This application claims the benefit of and incorporates by reference U.S. Provisional Application 61/536,340 (Texas Instruments docket number TI-69572), filed Sep. 19, 2011.

This invention relates to the field of integrated circuits. More particularly, this invention relates to double patterning technology for forming integrated circuits.

### BACKGROUND

Integrated circuits may be formed using photolithography processes with illumination sources having wavelengths more than twice a desired pitch of contact geometries the integrated circuits. Attaining desired tradeoffs between fabrication costs and fabrication yield may be difficult. For example, standard single photoresist patterns begin to blur at about the 45 nm feature size and 100 nm pitch (feature size plus space between features) when printing with 193 nm wavelength light.

Double patterning technology (DPT), illustrated in FIG. 1, may be used to print contact patterns with a pitch (geometry width plus space width) that is tighter than can be printed with a single patterning technology (SPT) where all contact geometries are on a single photo mask. The SPT contact pattern in FIG. 1A has a very tight pitch and cannot be printed using conventional lithography. By taking approximately half the contact geometries 22 of FIG. 1A and placing them on a first DPT photomask as shown in FIG. 1B and taking the remaining contact geometries 24 of FIG. 1A and placing them on a second DPT mask as shown in FIG. 1C, the contact pattern of FIG. 1A may be printed on an integrated circuit using conventional photolithography tools.

In a typical DPT process, first DPT contact photomask in FIG. 1B may be printed in photoresist and the pattern etched into a hardmask. Next second DPT contact photomask in FIG. 1B may be printed in photoresist and the pattern etched into the same hardmask. A contact etch may then be performed using the hardmask contact pattern containing the contacts of FIG. 1B plus the contacts of FIG. 1C to form the pattern in FIG. 1A on the integrated circuit. The DPT process is for description and not intended to be limiting. For example, both DPT photomasks may be printed in the same photoresist and the photoresist used to block the contact etch.

The size of integrated circuit geometries has been rapidly shrinking with each technology node. Technology node to technology node, design rules typically shrink to about 0.7 times previous node geometries. This means that the area of a geometry is reduced by approximately 50% (0.7×0.7=0.49) from one technology node to the next.

Contacts are typically drawn square and end up being approximately round on the integrated circuit. The reduction in area by approximately 50% significantly increases the resistance of contacts from one node to the next. This is not a significant problem for contacts to transistor gates, since very little current flows when charging the gate of a transistor, but is a significant problem for contacts to the source and drain of a transistor. Significant current flows through the source and drain contacts so the increased contact resistance due to the smaller area adds significant series resistance to the transistor and may significantly reduce transistor performance due to the increased resistance and due to the voltage drops across the high resistance.

### SUMMARY

An integrated circuit with long rectangular contacts to active where the active contact length is 2 times or more larger than the width and with short rectangular contacts to transistor gates where the transistor gate contact length is less than about 3 times the width. A method for forming an integrated circuit with long rectangular contacts to active where the active contact length is 2 times or more larger than the width and with short rectangular contacts to transistor gates where the transistor gate contact length is less than about 3 times the width.

### BRIEF DESCRIPTION OF THE DRAWINGS

FIGS. 1A, 1B, and 1C illustrate DPT technology

FIG. 2 is an example integrated circuit with contacts to active and contacts to gate formed according to principles of the invention.

FIG. 3 illustrates an illumination mode for printing square and short rectangular contacts.

FIG. 4 illustrates an illumination mode for printing long rectangular contacts parallel to the y-axis.

FIG. 5 illustrates an illumination mode for printing long rectangular contacts parallel to the x-axis.

FIG. 6 is the example integrated circuit of FIG. 2 plus a first level of interconnect.

FIG. 7 is a first level of interconnect pattern of FIG. 6.

FIG. 8 is a plan view of a narrow width transistor with contacts formed according to principles of the invention.

FIG. 9 is a plan view of transistors with local interconnect formed according to principles of the invention.

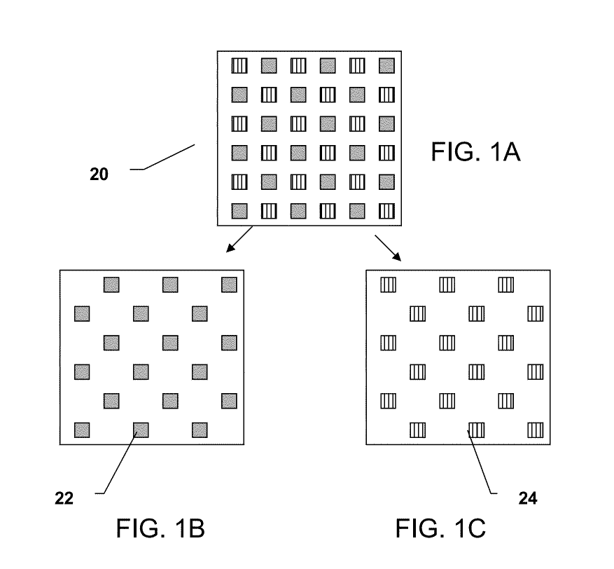

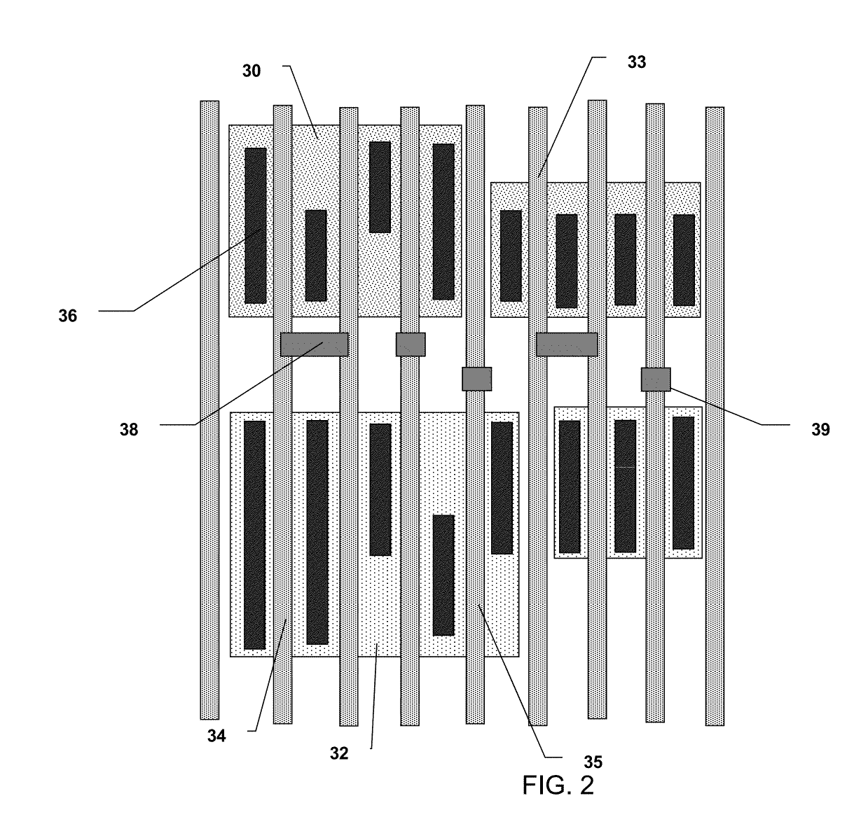

### DETAILED DESCRIPTION OF EXAMPLE EMBODIMENTS

In FIG. 2, an example standard cell with contacts formed according to embodiments is used to illustrate the embodiments. The standard cell is an example of a standard cell that may be found in a cell library. The embodiment invention is not limited to transistors in standard cells but may be used on any transistor in an integrated circuit.

The standard cell consists of n-type active areas 30 in which NMOS transistors are formed and p-type active areas 32 in which PMOS transistors are formed. Transistor gates 34 which cross both n-type active 30 and p-type active 32 form inverters. Transistor gate 33 which crosses n-type active only forms the gate of an NMOS transistor and transistor gate 35 which crosses p-type active only forms the gate of a PMOS transistor.

As shown in the example embodiment standard cell in FIG. 2, contacts to active are not the typical square or round contacts with equal x and y dimensions of prior nodes but are long rectangles parallel to the transistor gate geometries. The rectangular contact increases the area of the contact significantly reducing the resistance and significantly reducing the series resistance and voltage drop with a resultant improvement in transistor performance.

Also shown in FIG. 2 contacts to transistor gates 34 may be nearly square 39 or may be short rectangles 38 where the length is less than or equal to about twice the width. Because the contacts to gates are smaller the resistance is higher, but since little current flows through these contacts the higher resistance is tolerable. In addition the smaller size of the contacts to transistor gates enables a smaller area the standard cell than would be possible with large rectangular contacts.

The printing of long rectangular contacts may be significantly improved by selecting an illumination mode that is optimized for printing long rectangular geometries.

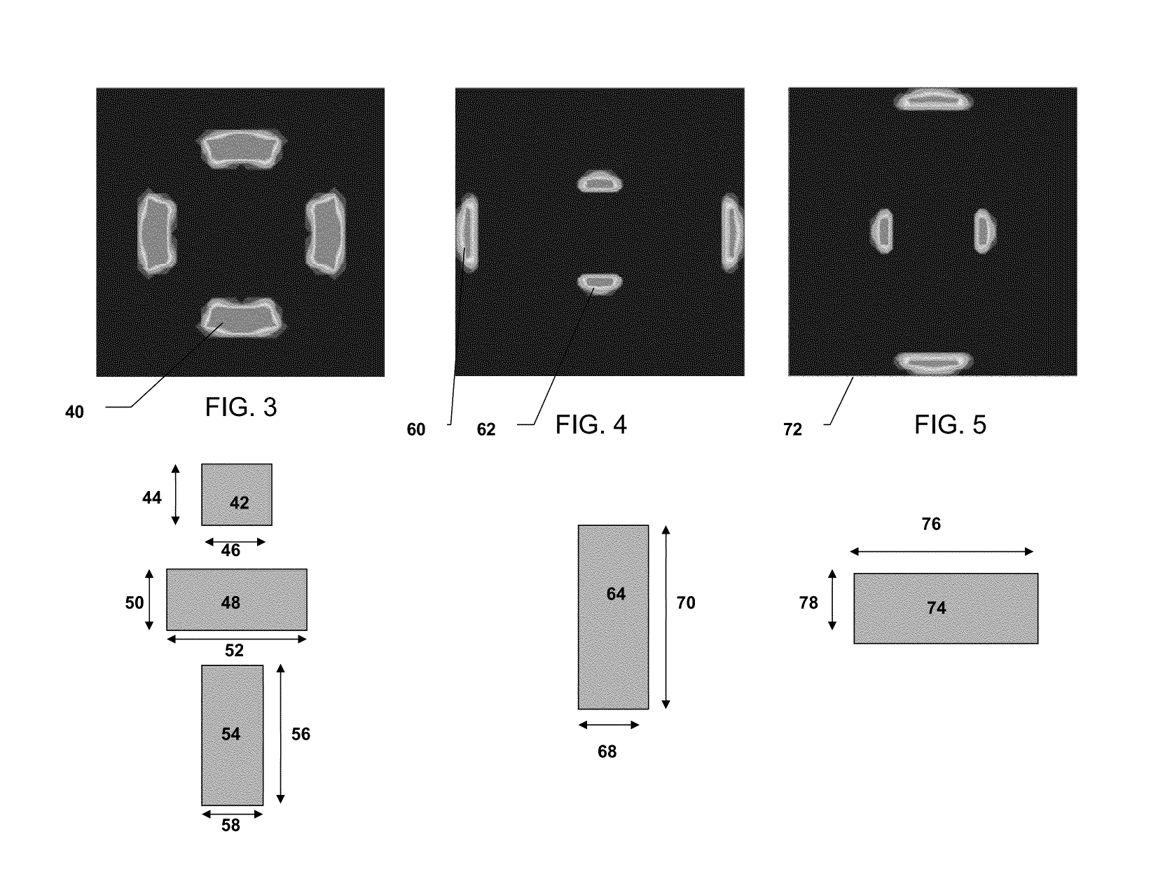

FIG. 3 shows annular illumination mode 40 with quadrupole illumination. This mode may be selected when printing square geometries 42 with equal length x 46 and y 44 dimensions. It also may be selected when printing short rectangular geometries such as 48 along the x-axis with a length 52 less than or equal to about twice the width 50 or short rectangular geometries such as 54 with a length 56 less than or equal to about twice the width 58.

FIG. 4 shows a quadrupole illumination optimized for printing long rectangles along the y-axis. This illumination mode has two strong dipole illumination areas 60 spaced wider apart along the x-axis than the quadrupole illumination areas 40 in FIG. 3, and two weaker dipole illumination areas 62 along the y-axis spaced closer together than the quadrupole illumination areas 40 in FIG. 3. The illumination in FIG. 4 is optimized for printing long rectangular geometries such as 64 parallel with the y-axis with the length 70 of the long rectangle about 3 times or greater than the width 68 of the rectangle. In an example embodiment the long rectangular contact length is greater than 2 times the width and preferably greater than 3 times the width.

The quadrupole illumination mode 72 shown in FIG. 5 is optimized for printing long rectangles 74 parallel to the x-axis with a length 76 of the long rectangle about 3 times or longer than the width 78.

The embodiment contacts illustrated in the standard cell in FIG. 2 take advantage of the optimized illumination modes for exposing each of the DPT contact photomasks. In this embodiment the long vertical rectangular contacts are placed on a first DPT photomask and printed using the illumination mode illustrated in FIG. 4 which is optimized for printing long vertical rectangles.

Contacts to transistor gate in this embodiment are placed on a second DPT photomask and printed using the illumination mode illustrated in FIG. 3 that is optimized for printing square and short rectangular contacts. In an example embodiment the length of the short rectangular contact is less than about 3 times the width and preferably less than about 2 times the width. Short rectangular contacts may also be approximately square.

In this embodiment long rectangular active contacts are placed on one DPT photomask and an illumination mode which is optimized for printing long rectangular contacts is selected for the widest possible processing margin and highest possible active contact yield. The long rectangular contacts to active significantly increase the contact area over conventional square or round contacts significantly reducing contact resistance and voltage drops, with a resultant increase in transistor performance.

In this embodiment contacts to the transistor gate are placed on a second DPT photomask and an illumination mode optimized for printing square or short rectangular contacts is selected to provide the widest possible processing margin and highest possible contact to transistor gate yield. Since transistor gate contacts pass little current the smaller contact size with higher contact resistance causes little voltage drop and no significant reduction in transistor performance. The smaller transistor gate contacts enable the contacts to be formed in a smaller area enabling smaller area standard cells and smaller area integrated circuits to be designed.

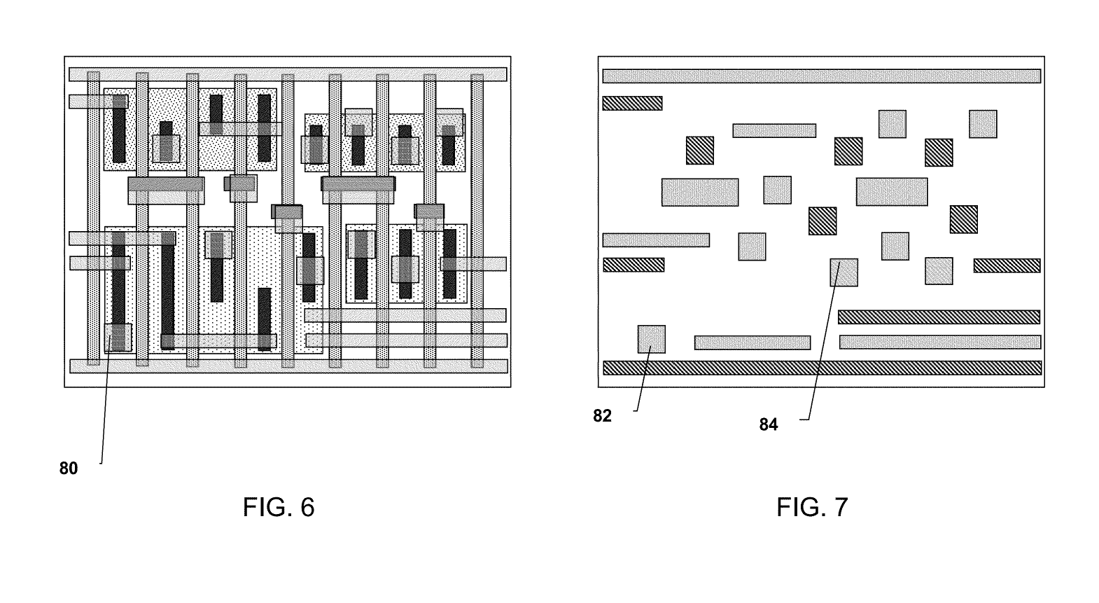

FIG. 6 shows the example standard cell of FIG. 2 with a first level of interconnect 80 formed over the contacts. This layer of interconnect may be termed metal-0 or metal-1.

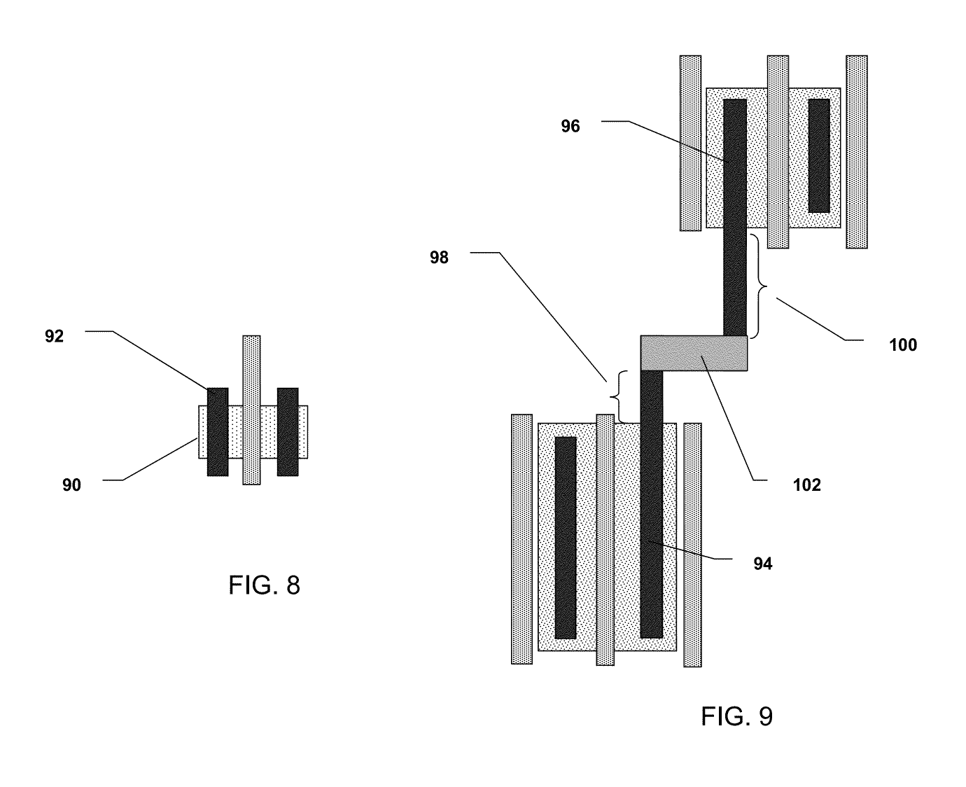

As shown in FIG. 7 this layer of interconnect 80 may be drawn to be DPT compatible with first color geometries 82 which may be placed on a first DPT compatible photomask and second color geometries 84 which may be place on a second DPT compatible photomask.

As shown in FIG. 8 the long rectangle active contact 92 may overhang a narrow active area 90 if desired to additionally reduce contact resistance. This may be desirable for narrow width transistors with fast switching speeds.

As is illustrated in FIG. 9, the embodiment contact method may also be used to form local interconnect. Long rectangular contacts 94 and 96 may extend over isolation dielectric along the y-axis to form local interconnect leads 98 and 100. The isolation dielectric may be shallow trench isolation (STI). A horizontal local interconnect bar 102 may additionally be used to electrically connect the local interconnect leads 98 and 100. The horizontal local interconnect bar 102 may be printed by placing the local interconnect geometry on the transistor gate contact mask. Relaxed local interconnect design rules for local interconnect geometries placed on the contact to gate photomask may be added for local interconnect geometries whose length exceeds about 2× the width to facilitate the printing of these geometries with the transistor gate contact illumination mode. The local interconnect geometries may be formed entirely over isolation dielectric if desired without touching an active or gate geometry.

After the long rectangular contacts to active, the short rectangular contacts to transistor gate, and the local interconnect geometries are printed in photoresist on the premetal dielectric (PMD) layer, a contact etch may be performed to etch the contacts down to the active and the transistor gates. If desired the contacts may first be etched into hardmask material overlying the PMD and the resist stripped prior to etching the contacts to minimize etch loading due to resist erosion in the etching plasma. The PMD layer typically is silicon dioxide or doped silicon dioxide on a relatively thin (about 30 nm) etch stop layer such as silicon nitride. The contact etch first etches the silicon dioxide layer stopping on the etch stop layer. The contact etch chemistry is then changed to etch the contact openings through the etch stop layer. The etch stop layer makes it possible to etch contacts over isolation dielectric without the contact etch penetrating through the isolation dielectric and causing a short to substrate.

The rectangular contacts to active, the short rectangular contacts to transistor gate, and the local interconnect geometries may then be filled with a metal such as CVD-W to form contacts to active, contacts to gate, and local interconnect. Additional layers such as interconnect, vias, and protective overcoat may then be formed to complete the integrated circuit.

By placing long rectangular contacts on a first DPT photomask and using an illumination mode optimized to print long rectangular geometries and by placing square and short rectangular contacts on a second DPT photomask and using an illumination mode optimized to print short rectangular geometries and square geometries, a contact process with improved process window, improved transistor performance, and improved yield may be achieved.

Those skilled in the art to which this invention relates will appreciate that many other embodiments and variations are possible within the scope of the claimed invention.

What is claimed is:

1. An integrated circuit, comprising:
A transistor with a transistor gate and with a source/drain active area;
a long rectangular contact on said source/drain active area parallel to said transistor gate where a length of said long rectangular contact is greater than about 2 times a width of said long rectangular contact; and
a short rectangular contact on said transistor gate perpendicular to said transistor gate where a length of said short rectangular contact is less than or equal to about 3 times a width of said short rectangular contact.

2. The integrated circuit of claim 1 where said transistor is and NMOS or PMOS transistor.

3. The integrated circuit of claim 1 where said short rectangular contact is approximately square.

4. The integrated circuit of claim 1 where said length of said long rectangular contact is approximately 3 times said width of said long rectangular contact.

5. The integrated circuit of claim 1 where said length of said short rectangular contact is approximately 2 times said width of said short rectangular contact.

6. The integrated circuit of claim 1 where said first long rectangular contact overhangs said source/drain active area.

7. The integrated circuit of claim 1 where said source/drain active area overhangs said first long rectangular contact.

10. The integrated circuit of claim 1 further comprising:
a local interconnect where said local interconnect further comprises at least one of said long rectangular contacts over isolation dielectric.

11. The integrated circuit of claim 1 further comprising:
a local interconnect where said local interconnect further comprises
a first long rectangular contact over isolation dielectric,
a second said long rectangular contact over said isolation dielectric and parallel to said first long rectangular contact; and
a local interconnect geometry perpendicular to said first long rectangular contact connecting said first long rectangular active contact to said second long rectangular contact.

12. A process of forming an integrated circuit, comprising the steps:
making a first photomask with long rectangular contacts to active on said first photomask;
making a second photomask with short rectangular contacts to transistor gates on said second photomask;
forming in said integrated circuit a transistor with source/drain active areas, and with a transistor gate;
printing said a long rectangular contact on said source/drain active area using said first photomask and using an illumination mode optimized to print said long rectangular contact with a length about 2 times or greater than a width of said long rectangular contact where said long rectangular contact is printed parallel to said transistor gate;
printing said short rectangular contact to said transistor gate on said integrated circuit using said second photomask and using an illumination mode optimized to print short rectangular contacts with a length less than about 3 times a width of said short rectangular contact.

13. The process of claim 12 further comprising forming said long rectangular contact where all of said long rectangular contact overlies said source/drain active area.

14. The process of claim 12 further comprising forming said long rectangular contact where a first portion of said long rectangular contact overlies said source/drain active area and where a second portion of said long rectangular contact overlies isolation dielectric.

15. The process of claim 12 further comprising forming said short rectangular contact approximately round.

16. The process of claim 12 further comprising:
forming a local interconnect geometry on said first photomask where said local interconnect geometry is a rectangle with a length greater than or equal to about 3 times a width of said rectangle and where a portion of said local interconnect geometry overlies isolation dielectric;
printing said local interconnect geometry in photoresist on a dielectric on said integrated circuit using an illumination mode optimized for printing said long rectangular contacts;
etching said local interconnect geometry into said dielectric; and
filling said local interconnect geometry with metal.

17. The process of claim 12 further comprising:
forming a first and a second local interconnect geometry on said first photomask where said first and said second local interconnect geometry are rectangles with a length greater than or equal to about 3 times a width of said rectangles and where a portion of said local interconnect geometries overlie an isolation dielectric;
forming a third local interconnect geometry on said second photomask where said third local interconnect geometry is perpendicular to said first and said second local interconnect geometries and where said third local interconnect geometry connects said first local interconnect geometry to said second local interconnect geometry.
printing said first and sais second local interconnect geometries in photoresist on dielectric on said integrated circuit using an illumination mode optimized for printing said long rectangular contacts;
printing said third local interconnect geometry in photoresist on said dielectric on said integrated circuit using an illumination mode optimized for printing said short rectangular contacts;
etching said first, said second, and said third local interconnect geometries into said dielectric; and
filling said first, said second, and said third local interconnect geometries with metal.

18. The process of claim 17 where said third local interconnect geometry is less than or equal to about 2 times said local interconnect geometry width and where a width of said third local interconnect geometry is about the same as said width of said short rectangular contact.

19. The process of claim 17 where said third local interconnect geometry is longer than about 2 times said local interconnect geometry width and where a width of said third local interconnect geometry is greater than said width of said short rectangular contact.
